(19) United States
(12) Patent Application Publication
(10) Pub. No.: US 2025/0374594 A1
(43) Pub. Date: Dec. 4, 2025

(54) MOAT TERMINATION STRUCTURE FOR A SEMICONDUCTOR DEVICE AND METHOD OF FABRICATING THE SAME

(71) Applicant: IDEAL SEMICONDUCTOR DEVICES, INC., Bethlehem, PA (US)

(72) Inventors: Stanislav I. Soloviev, Breinigsville, PA (US); Mark E. Granahan, Allentown, PA (US); Philip Rutter, Bethlehem, PA (US); Lawrence A. Goodman, Plainsboro, NJ (US)

(21) Appl. No.: 18/676,692

(22) Filed: May 29, 2024

(51) Int. Cl. H01L 29/78; H01L 21/762; H01L 29/06

(52) U.S. Cl. CPC H10D 30/665; H01L 21/76224; H10D 62/102

(57) ABSTRACT

A moat termination structure is provided for use in a semiconductor device including an active region, in which one or more active devices are formed, and an edge termination region adjacent to the active region, in which the moat termination structure is formed. The moat termination structure includes a plurality of dielectric pillars in the edge termination region, each of the plurality of dielectric pillars extending in a first direction perpendicular to an upper surface of the semiconductor device. The moat termination structure further includes one or more dielectric structures in the edge termination region, each of the dielectric structures extending in the first direction and disposed between two dielectric pillars adjacent to one another in a second direction parallel to the upper surface of the semiconductor device.

### BACKGROUND

The present invention relates generally to semiconductor devices and fabrication, and, more particularly, to enhanced termination structures for use in a semiconductor device, and methods of fabricating such structures.

A high voltage semiconductor device (e.g., power metal-oxide semiconductor field-effect transistor (MOSFET), Schottky diode, insulated gate bipolar junction transistor (IGBT), etc.) typically comprises an active region, in which the semiconductor device or other circuits and/or elements are formed, and a termination region which serves to electrically isolate the semiconductor device from the surrounding substrate and/or from the device package. The termination region, which is typically disposed around a periphery or edge of the die and surrounds the active region, ensures that the active region of the device is protected from high voltages, and that the device breakdown voltage of the device is as high as possible.

Some high voltage semiconductor devices, such as power MOSFETs or IGBTs, utilize a lightly doped drift region that may be terminated in such a way as to ensure the optimum distribution of electric field or potential lines which is important to achieve the full voltage rating of the device. In order to be effective, such a termination region should have a higher voltage-withstanding capability than the active region of the device. Therefore, an edge termination region is an important part of the device design to ensure lateral blocking of potentially damaging voltages between the active region and the edge of the die.

There are several different edge termination designs that have been used in power semiconductor devices, including moat termination, junction termination extension (JTE), and bevel termination. In a moat termination approach, as the name suggests, a wide and deep trench (i.e., moat) is formed in an edge termination region of the device and the trench is then filled with a high-quality dielectric material, such as, for example, bisbenzocyclobutene (BCB) or polyimide.

Known methods for forming a moat termination are based on etching a wide and deep trench in the edge termination region of the semiconductor device. It is not practical, however, to fill wide and deep trenches with high-quality dielectric materials due at least in part to cost. Furthermore, dielectrics used to fill the trench in a moat termination design typically contain impurities that can result in device failure during high-temperature testing. Additionally, wide and deep trenches filled with solid dielectric material can cause mechanical stresses in a wafer in which the device is formed.

### SUMMARY

The present invention, as manifested in one or more embodiments, beneficially provides an enhanced moat termination structure for use in an edge termination region of a semiconductor device. In one or more embodiments, the moat termination structure comprises a plurality of dielectric pillars and air gaps arranged in an alternating manner (i.e., each air gap laterally separating adjacent dielectric pillars) in an edge termination region of the semiconductor device.

In accordance with an embodiment of the present disclosure, a moat termination structure is provided for use in a semiconductor device including an active region, in which one or more active devices are formed, and an edge termination region adjacent to the active region, in which the moat termination structure is formed. The moat termination structure includes a plurality of dielectric pillars in the edge termination region, each of the plurality of dielectric pillars extending in a first direction perpendicular to an upper surface of the semiconductor device, and one or more dielectric structures in the edge termination region, each of the dielectric structures extending in the first direction and disposed between two dielectric pillars adjacent to one another in a second direction parallel to the upper surface of the semiconductor device.

In some embodiments, each of the plurality of dielectric pillars in the moat termination structure includes a first dielectric material layer defining sidewalls and a bottom of the dielectric pillar, and a second dielectric material layer disposed on the sidewalls and the bottom of the first dielectric material layer. Sidewalls and top and bottom surfaces of the second dielectric material layer define a first interior space of the dielectric pillar. In some embodiments, each of the one or more dielectric structures includes a third dielectric material layer defining sidewalls and top and bottom surfaces of the dielectric structure, and a second interior space defined by the third dielectric material layer.

In accordance with another embodiment of the present disclosure, a semiconductor device is provided having an active region and an edge termination region, the edge termination region being laterally adjacent to the active region. The semiconductor device includes a semiconductor layer structure comprising a drift region, the drift region including an active region, including at least one active element therein, and an edge termination region extending around at least a portion of a perimeter of the active region when viewed in plan view. The semiconductor device further includes a moat termination structure in the edge termination region. The moat termination structure includes a plurality of dielectric pillars, each of the plurality of dielectric pillars extending at least partially through the drift region in a first direction perpendicular to an upper surface of the semiconductor layer structure, and one or more dielectric structures, each of the dielectric structures extending at least partially through the drift region in the first direction and disposed between two dielectric pillars adjacent to one another in a second direction parallel to the upper surface of the semiconductor layer structure.

In accordance with an embodiment of the present disclosure, a method is provided for fabricating a moat termination structure for use in a semiconductor device including an active region, in which one or more active devices are formed, and an edge termination region adjacent to the active region, in which the moat termination structure is formed. The method includes: forming a plurality of dielectric pillars in the edge termination region, each of the plurality of dielectric pillars extending in a first direction perpendicular to an upper surface of the semiconductor device; and forming one or more dielectric structures in the edge termination region, each of the dielectric structures extending in the first direction and disposed between two dielectric pillars adjacent to one another in a second direction parallel to the upper surface of the semiconductor device.

In accordance with another embodiment of the present disclosure, a method of forming a semiconductor device comprises: providing a semiconductor layer structure comprising a drift region, the drift region including an active region, including at least one active element therein, and an edge termination region extending around at least a portion of a perimeter of the active region when viewed in plan view; and forming a moat termination structure in the edge termination region. Forming the moat termination structure includes: forming a plurality of dielectric pillars, each of the plurality of dielectric pillars extending at least partially through the drift region in a first direction perpendicular to an upper surface of the semiconductor layer structure; and forming one or more dielectric structures, each of the dielectric structures extending at least partially through the drift region in the first direction and disposed between two dielectric pillars adjacent to one another in a second direction parallel to the upper surface of the semiconductor layer structure.

As the term may be used herein, “facilitating” an action includes performing the action, making the action easier, helping to carry the action out, or causing the action to be performed. Thus, by way of example only and without limitation, in the context of a processor-implemented semiconductor fabrication method, instructions executing on one processor might facilitate an action carried out by instructions executing on a remote processor, by sending appropriate data or commands to cause or aid the action to be performed. For the avoidance of doubt, where an actor facilitates an action by other than performing the action, the action is nevertheless performed by some entity or combination of entities.

Techniques of the present invention can provide substantial beneficial technical effects. By way of example only and without limitation, techniques according to embodiments of the invention may provide one or more of the following advantages, among other benefits:
provides a compact edge termination region that minimizes additional semiconductor area consumption;
minimizes additional process steps, thereby reducing overall cost and fabrication complexity and improves yield;
provides an edge termination region that achieves a high breakdown voltage consistent with that in the active region, and can be optimized to reduce mechanical stresses in the semiconductor device;
compatible with other edge termination features that are used to improve an effectiveness of edge termination structures, including, for example, inner field plates and outer field plates;
maximizes the breakdown voltage of the edge termination region.

These and other features and advantages of the present invention will become apparent from the following detailed description of illustrative embodiments thereof, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIG. 1A is a schematic plan view depicting a top surface of an exemplary semiconductor device in which embodiments of the present inventive concept may be formed;

FIG. 1B is a schematic cross-sectional view depicting a portion of the exemplary semiconductor device of FIG. 1A, taken along line A-A′;

FIG. 2A is a schematic cross-sectional view depicting at least a portion of an exemplary IC die including an enhanced moat termination structure, according to one or more embodiments of the present inventive concept;

FIG. 2B is an enlarged cross-sectional view of the region B in the exemplary IC die shown in FIG. 2A;

FIG. 3 is a flow diagram depicting an illustrative method 300 of fabricating a semiconductor device 200 including an enhanced moat termination structure, according to one or more embodiments of the present inventive concept;

FIG. 4A is a schematic cross-sectional view depicting the formation of deep trenches in an active region and moat region of an example IC die, according to one or more embodiments of the present inventive concept;

FIG. 4B is a schematic plan view depicting at least a portion of the example IC die shown in FIG. 4A;

FIGS. 4C-4E are schematic plan views depicting at least a portion of example alternative configurations of an enhanced moat termination structure, according to embodiments of the inventive concept; and

FIGS. 5-10 are schematic cross-sectional views depicting at least a portion of intermediate processes for fabricating an exemplary IC die including an enhanced moat termination structure, according to one or more embodiments of the present inventive concept.

It is to be appreciated that elements in the figures are illustrated for simplicity and clarity. Common but well-understood elements that may be useful or necessary in a commercially feasible embodiment are not necessarily shown in order to facilitate a less hindered view of the illustrated embodiments.

### DETAILED DESCRIPTION

Principles of the present invention, as manifested in one or more embodiments thereof, will be described herein in the context of illustrative moat termination structures for use in a power semiconductor device, and methods for fabricating such structures. The novel moat termination structure according to embodiments of the invention may have beneficial application, for example, in a power device or power system environment for providing direct current (DC)-DC or alternating current (AC)-DC conversion. It is to be appreciated, however, that the present inventive concepts are not limited to the specific structures and/or methods illustratively shown and described herein. Rather, it will become apparent to those skilled in the art given the teachings herein that numerous modifications can be made to the embodiments shown that are within the scope of the claimed invention. That is, no limitations with respect to the embodiments shown and described herein are intended or should be inferred.

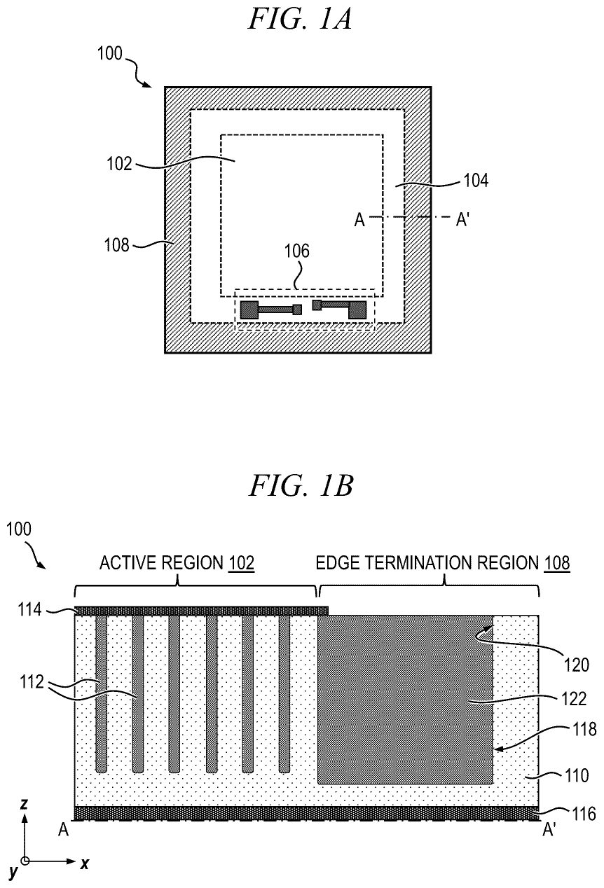

FIG. 1A is a plan view depicting a top surface of an exemplary integrated circuit (IC) die 100 in which embodiments of the present inventive concept may be formed. The IC die 100 includes an active region 102 and an inactive region 104. The inactive region 104 may include one or more regions 106 where pads, buses or other structures are formed (e.g., interconnections, etc.) without disposing any active devices under these structures, and an edge termination region 108 that extends around (i.e., surrounds) the active region 102 about a periphery (i.e., outside edge) of the IC die 100. Depending on the particular application, the active region 102 may include one or more active semiconductor circuit elements or semiconductor device cells formed therein, such as, for example, one or more metal-oxide-semiconductor field-effect transistors (MOSFETs), diodes, Schottky diodes, junction barrier Schottky (JBS) diodes, PIN diodes, insulated-gate bipolar transistors (IGBTs), among other circuit elements. The IC die 100 may embody wide bandgap semiconductor devices, for example silicon carbide (SiC)-based devices. The edge termination region 108 may be configured to reduce a concentration of an electric field at the edges of the IC die 100 in order to improve the performance thereof. For example, the edge termination region 108 may increase a breakdown voltage of the IC die 100 and decrease a leakage current of the IC die 100 over time. By way of example, the edge termination region 108 may include one or more guard rings, a junction termination extension (JTE), and combinations thereof.

FIG. 1B is a cross-sectional view depicting a portion of the exemplary IC die 100 shown in FIG. 1A, taken along line A-A′. Referring to FIG. 1B, the IC die 100, which may comprise one or more vertically conducting devices, includes the active region 102 surrounded by the edge termination region 108. The term “surrounded” (or “surrounds,” “surrounding,” or like terms), as may be used herein, is intended to broadly refer to an element, structure or layer that extends around, envelops, encircles, or encloses another element, structure or layer on all sides, although breaks or gaps may also be present. Thus, for example, a material layer having voids or gaps therein may still “surround” another layer which it encircles. The active region 102 may comprise an n-type epitaxial layer 110 in which a layer of p-type material (not explicitly shown) is preferably formed proximate an upper surface of the epitaxial layer (depending on the type of device being formed), although embodiments of the invention are not limited to this specific arrangement. For example, in some embodiments, a p-type epitaxial layer 110 may be employed. As will be apparent to those skilled in the art, n-type material used to form the epitaxial layer 110, which may be referred to herein as a drift region, may be formed by doping intrinsic semiconductor material (e.g., silicon) with an n-type (donor) dopant element, such as, for example, phosphorous, arsenic, etc., at a prescribed doping concentration level. Likewise, the p-type material layer can be formed by doping the semiconductor material with a p-type (acceptor) dopant element, such as, for example, boron, at a prescribed doping concentration. Although shown as a single layer, the epitaxial layer 110 may embody one or more layers of a wide bandgap semiconductor material, such as, for example, SiC.

The active region 102 may include a plurality of active trench structures 112. Each of the active trench structures 112 may be formed as a high aspect ratio trench that is at least partially filled with a dielectric material. The term “filled” (or “filling” or like terms), as may be used herein, is intended to refer to either completely filling a defined space (e.g., high aspect ratio trench) or partially filling the defined space; that is, the defined space need not be entirely filled but may, for example, be partially filled or have voids, gaps or other spaces throughout. A standard deposition process may be used to fill the active trench structures 112.

The active trench structures 112 may extend at least partially through the epitaxial layer 110 in a substantially vertical direction (i.e., z direction) perpendicular to an upper surface of the IC die 100. In one or more embodiments, the active trench structures 112 may extend at least twenty-five percent (25%) through the epitaxial layer 110; in some embodiments, the active trench structures 112 may extend entirely through the epitaxial layer 110 and into an underlying substrate (not explicitly shown, but implied) on which the epitaxial layer 110 may be formed. A first metal layer 114 may be formed on an upper surface of the active trench structures 112 and an upper surface of at least a portion of the epitaxial layer 110 between adjacent active trench structures 112 (i.e., active mesa). In one or more embodiments, the active trench structures 112 may be used for charge balancing at least a portion of the active region 102. A second metal layer 116 may be provided on a bottom surface of the IC die 100. This second metal layer 116 may be used to provide electrical connection to a terminal or electrode (e.g., drain terminal, cathode, etc.) of one or more devices formed in the IC die 100.

The edge termination region 108 may include a moat structure 118, which may be formed as a deep, wide trench 120 in the epitaxial layer 110 that is at least partially filled with a dielectric material 122. The term “moat” as used herein is intended to refer broadly to a region adjacent to an active region (e.g., 102) where part of the epitaxial silicon has been removed and at least partially filled with an insulating material. The moat structure 118 may be formed as a RESURF (reduced surface field) structure, in one or more embodiments.

The moat structure 118 in the edge termination region 108 may surround the active region 102, but configurations are contemplated where the moat structure 118 may be arranged on less than all four sides of the active region 102 (e.g., one, two or three sides only). Although not critical, in one or more embodiments, a width (in the x direction) of the moat structure 118 may be significantly larger relative to a width (in the x direction) of each of the active trench structures 112. For example, in some embodiments, the width in the x direction of each of at least a subset of the active trench structures 112 may be about 1 micrometer (μm), and the width in the x direction of the moat structure 118 may be about 10 μm, although embodiments are not limited thereto. More generally, a width of the moat structure 118 in the x direction should be greater than or equal to a ratio E/BV, where E is the critical field of the dielectric material 122 used to fill the moat structure 118 and BV is the breakdown voltage of the device in the active region 102.

The moat structure 118 may be formed using a single trench etch to form a wide and deep trench at least partially through the epitaxial layer 110 in the edge termination region 108 of the IC die 100, and then filling the trench with a high-quality dielectric material 120, such as bisbenzocyclobutene (BCB) or polyimide. Conventional approaches for forming a moat termination structure, however, have several disadvantages. For example, as previously stated, it is generally not practical to fill wide and deep trenches with high-quality dielectric materials due at least in part to cost. Additionally, dielectric materials used to fill the trench in a moat termination structure typically contain impurities that can result in device failure during high-temperature testing. Moreover, wide and deep trenches filled with solid dielectric material may cause mechanical stresses in a wafer in which the device is formed, leading to reduced device yield or reliability issues.

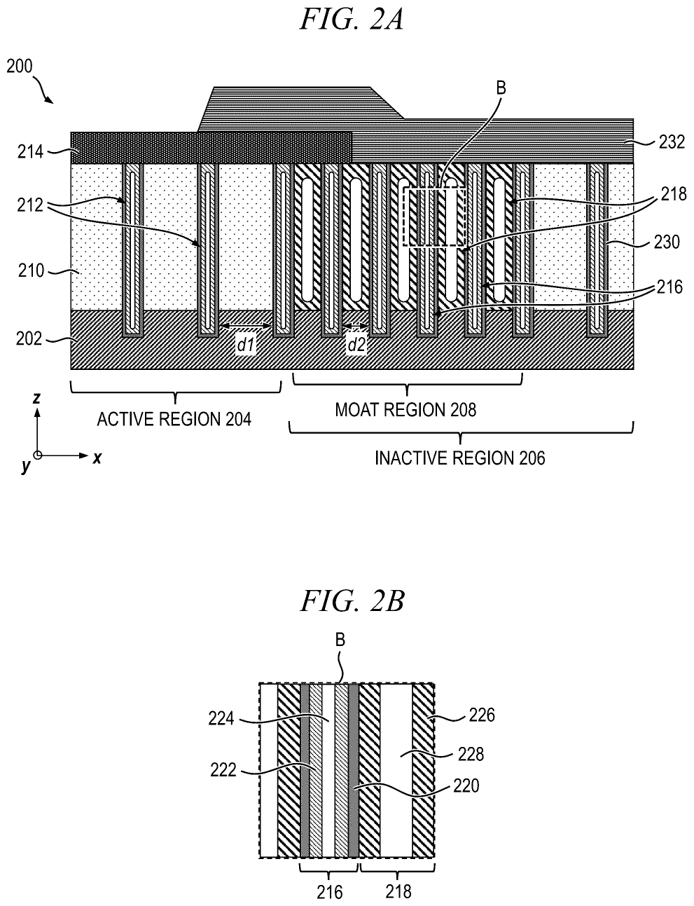

In order to eliminate or reduce problems associated with conventional moat termination designs, aspects of the present inventive concept provide a moat termination structure that includes an array of dielectric pillars and air gaps, rather than a single wide and deep trench filled with a solid high-quality dielectric material. The term “air” or “air gap,” as may be used herein, is intended to broadly refer to the atmosphere or other gases that may be present during a manufacturing process. FIG. 2A is a cross-sectional view depicting at least a portion of an exemplary IC die 200 including an enhanced moat termination structure, according to one or more embodiments of the invention. FIG. 2B is an enlarged cross-sectional view of the region B shown in FIG. 2A. Referring to FIGS. 2A and 2B, the IC die 200 includes a substrate 202 comprising an active region 204 and an inactive region 206 laterally adjacent to the active region 204 (i.e., spaced apart from the active region 204 in the x direction). The inactive region 206 may be consistent with the edge termination region 108 in the semiconductor device 100 shown in FIG. 1B. The substrate 202 may comprise an n-type substrate, although it is contemplated that a p-type substrate 202 may alternatively be employed. An n-type substrate 202 may be formed by heavily doping intrinsic semiconductor material (e.g., silicon) with an n-type (donor) dopant element, such as, for example, phosphorous, arsenic, etc., at a prescribed doping concentration level (e.g., about 10¹⁸ to about 10²⁰ atoms per cubic centimeter). Alternatively, a p-type substrate 202 may be formed by heavily doping intrinsic semiconductor material with a p-type (acceptor) dopant element, such as, for example, boron, etc., at a prescribed doping concentration level.

The inactive region 206 may include regions where pads, buses or other structures are formed (e.g., gate pads and/or gate buses, not explicitly shown) without having any active devices disposed under these structures, and an edge termination region that extends around (i.e., surrounds) the active region 204 about a periphery (i.e., outside edge) of the IC die 200. Depending on the particular application, the active region 204 may include one or more active semiconductor circuit elements formed therein, such as, for example, one or more metal-oxide-semiconductor field-effect transistors (MOSFETs), diodes, Schottky diodes, junction barrier Schottky (JBS) diodes, PIN diodes, and/or insulated-gate bipolar transistors (IGBTs), among other circuit elements. The IC die 200 may embody wide bandgap semiconductor devices, for example silicon carbide (SiC)-based devices. The inactive region 206 includes a moat region (i.e., edge termination region) 208 configured to reduce a concentration of an electric field at the edges of the IC die 200 in order to improve the performance thereof, such as providing increased breakdown voltage. As will be described in further detail herein below, the moat region includes a moat structure that is not formed as a single wide and deep trench, but rather comprises an array of dielectric pillars separated by air gaps.

The IC die 200 further includes an epitaxial layer 210 on the substrate 202. The epitaxial layer 210, which may be referred to as a drift layer or drift region, extends laterally (i.e., in an x direction and/or a y direction, parallel to an upper surface of the substrate 202) from the active region 204 into the inactive region 206. The epitaxial layer 210 may comprise an n-type epitaxial layer, although it is contemplated that a p-type epitaxial layer 210 may alternatively be employed. As will be apparent to those skilled in the art, n-type material used to form the epitaxial layer 210 may be formed by doping intrinsic semiconductor material (e.g., silicon) with an n-type (donor) dopant element, such as, for example, phosphorous, arsenic, etc., at a prescribed doping concentration level. The epitaxial layer 210 may be more lightly doped with respect to the substrate 202 (e.g., about 10¹³ to about 10¹⁷ atoms/cm³). Likewise, a p-type epitaxial layer 210 can be formed by doping the semiconductor material with a p-type dopant element at a prescribed doping concentration level. Although shown as a single layer, the epitaxial layer 210 may embody one or more layers of a wide bandgap semiconductor material, such as, for example, SiC, although embodiments are not limited thereto.

The active region 204 may include a plurality of active trench structures 212, each of at least a subset of the active trench structures 212 extending vertically (i.e., in a z direction, perpendicular to the upper surface of the substrate 202) from an upper surface of the epitaxial layer 210, at least partially into the epitaxial layer 210. In some embodiments, the active trench structures 212 may extend through the epitaxial layer 210 and at least partially into the underlying substrate 202. The active trench structures 212 may be separated from one another in the x direction by a prescribed distance, d1; this distance d1 may be referred to herein as a pitch of the active trench structures. Each of the active trench structures 212 may be formed as a high aspect ratio trench (e.g., having a depth in the z direction that is greater than about ten times its width in the x direction). In some embodiments, a width in the x direction of each of at least a subset of the active trench structures 212 may be about 1 micrometer (μm), although embodiments are not limited thereto. The active trenches are then at least partially filled with a dielectric material; the dielectric material filling the active trenches may include an air gap.

During a metallization process, a metal (i.e., conductor) layer 214 may be formed on upper surfaces of at least a subset of the active trench structures 212 and on at least a portion of the upper surface of the epitaxial layer 210, including the epitaxial layer 210 between adjacent active trench structures 212. An end of the metal layer 214 may extend laterally (e.g., in the x direction) into the inactive region 206 over a portion of the moat region 208. This extension of the metal layer 214 over the moat region 208 may serve as a field plate for controlling the electric field distribution at an edge of the active region 204.

The moat region 208 includes a moat termination structure comprising a plurality of dielectric pillars with high-quality dielectric regions disposed between adjacent dielectric pillars. Specifically, in one or more embodiments, the moat termination structure includes a plurality of dielectric pillars 216 interspersed with high-quality dielectric structures 218. Each of the dielectric pillars 216 may extend vertically (i.e., in the z direction) at least partially into or through the epitaxial layer 210 in the moat region 208. In some embodiments, the dielectric pillars 216 may extend partially into the substrate 202. The dielectric pillars 216 may be spaced apart from one another in the x direction by a distance d2, which may be less than the distance dl between adjacent active trench structures 212; that is, the pitch between adjacent dielectric pillars 216 in the moat region 208 may be less than the pitch between adjacent active trench structure 212 in the active region 204.

In one or more embodiments, each of the dielectric pillars 216 may have a width in the x direction that is the same as the width of each of the active trench structures 212. In some embodiments, the width in the x direction of each of the dielectric pillars 216, like the width in the x direction of each of the active trench structures 212, is about 1 μm, although embodiments are not limited thereto. The dielectric pillars 216 may be formed as high aspect ratio trenches, for example using a deep trench etch process. A high-quality dielectric layer 220 (FIG. 2B), such as, for example, tetraethyl orthosilicate (TEOS) film, is then provided (e.g., using a deposition process) on sidewalls and a bottom of the trenches. These trenches forming the dielectric pillars 216 are then at least partially filled with a layer of high-quality dielectric material 222 (FIG. 2B), such as, for example, borophosphosilicate glass (BPSG) or the like, using a deposition process. Depending on the cross-sectional thickness of the deposited dielectric material 222, a first air gap 224 (FIG. 2B) may be provided in each of at least a subset of the dielectric pillars 216; that is, each of at least the subset of dielectric pillars 216 comprises an interior space, defined by sidewalls and top and bottom surfaces of the dielectric material 222, forming the first air gap 224. In some embodiments, a gas (other than or in addition to air) may at least partially fill the interior space forming the first air gap 224. In one or more embodiments, the dielectric pillars 216 may be formed concurrently with the active trench structures 212 in the same process step and using the same mask layer. An example process for fabricating the moat termination structure according to one or more embodiments will be described in further detail herein below.

The moat termination structure further includes one or more high-quality dielectric structures 218. Each of the high-quality dielectric structures 218 may be disposed between adjacent dielectric pillars 216. Each of the high-quality dielectric structures 218 may extend vertically into the epitaxial layer 210 and may be spaced apart from one another in the x direction. In one or more embodiments, a vertical depth (i.e., in the z direction) of each of the high-quality dielectric structures 218 may be less than a vertical depth of each of the dielectric pillars 216. In some embodiments, the high-quality dielectric structures 218 do not extend into the substrate 202 but are disposed on the upper surface of the substrate 202, whereas the dielectric pillars may extend at least partially into the substrate 202.

Each of the high-quality dielectric structures 218 may be formed as trenches having opposing sidewalls defined by sidewalls of adjacent dielectric pillars 216 and a trench bottom defined by the upper surface of the substrate 202. A layer of high-quality dielectric material 226 (FIG. 2B) is deposited in these trenches, on the sidewalls and bottom surfaces of the trenches (e.g., conformally covering the sidewalls and bottom surfaces of the trenches). The term “conformally” (or “conformal,” or like terms), as may be used herein in the context of a material layer or coating, is intended to refer broadly to a material layer or coating having a substantially uniform cross-sectional thickness relative to the contour of a surface to which the material layer is applied. Each of at least a subset of the high-quality dielectric structures 218 includes a second air gap 228 (FIG. 2B). Mechanical stresses in the IC die 200 may be beneficially optimized by controlling a width in the x direction of the second air gaps 228.

The inactive region 206 of the IC die 200 may include one or more boundary trench structures 230 proximate an edge (i.e., periphery) of the inactive region 206 outside of the moat region 208, farther from the active region 204 in the x direction. The boundary trench structure 230 may be formed in a manner consistent with the active trench structures 212. A distance in the x direction between a last one of the dielectric pillars 216 closest to the edge of the IC die 200 and the boundary trench structure 230 may be greater than the spacing d2 between adjacent dielectric pillars 216. In some embodiments, the last one of the dielectric pillars 216 may be spaced apart in the x direction from the boundary trench structure 230 by the distance d1, although embodiments are not limited thereto.

A passivation layer 232 may be provided on an upper surface of the IC die 200, including an upper surface of the dielectric pillars 216, an upper surface of the high-quality dielectric structures 218, at least a portion of the exposed upper surface of the epitaxial layer 210 in the inactive region 206, and an upper surface of the boundary trench structure 230. The passivation layer 232 may extend laterally (i.e., in the x direction and/or y direction), parallel to the upper surface of the substrate 202, from the edge of the IC die 200 across the upper surface of the inactive region 206 and, in some embodiments, may extend onto at least a portion of an upper surface of the metal layer 214. The term “exposed” (or “expose,” or like terms) may be used herein to describe relationships between elements and/or with reference to intermediate processes in fabricating a semiconductor device, but may not require exposure of a particular element in the completed device. Likewise, the term “not exposed” may be used to describe relationships between elements and/or with reference to intermediate processes in fabricating a semiconductor device, but may not require a particular element to be unexposed in the completed device.

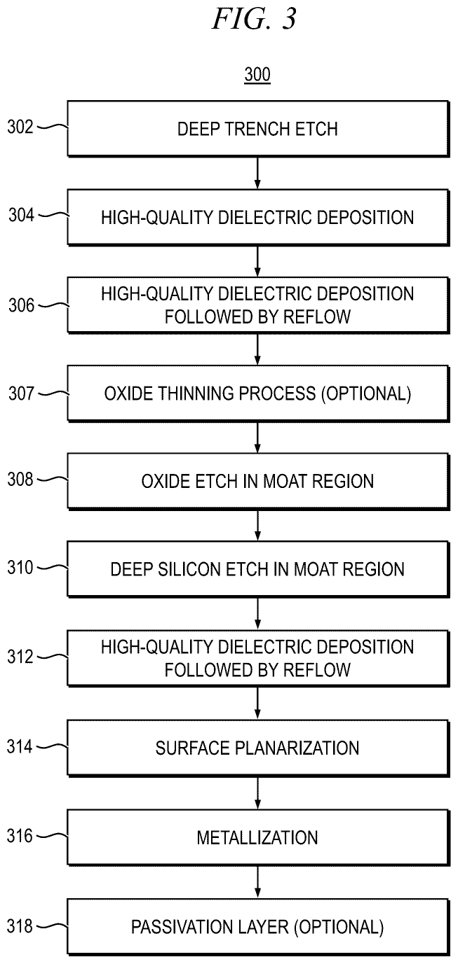

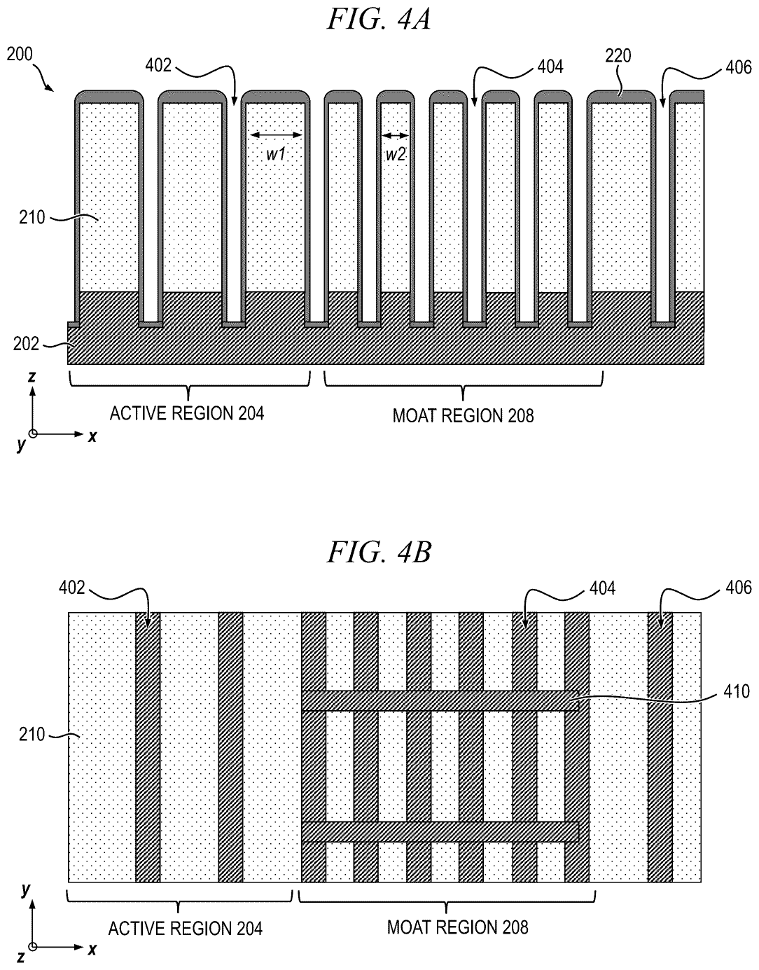

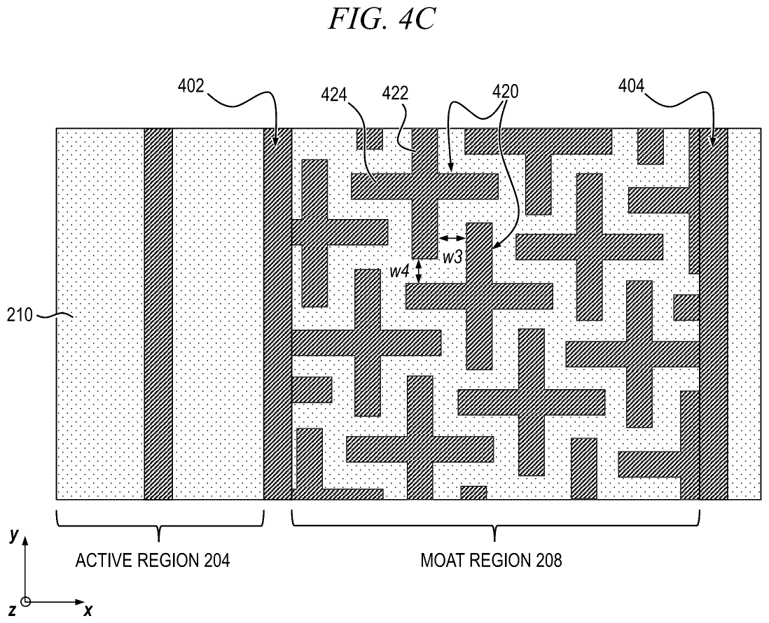

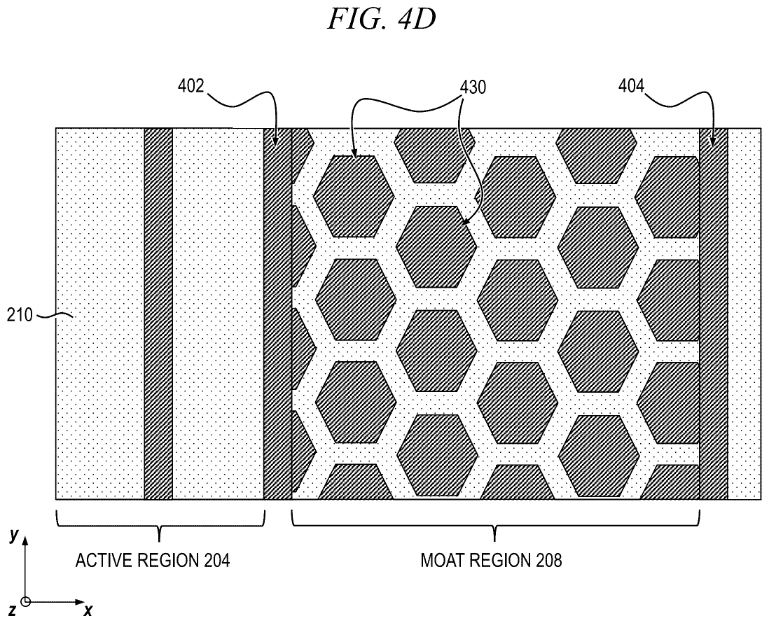

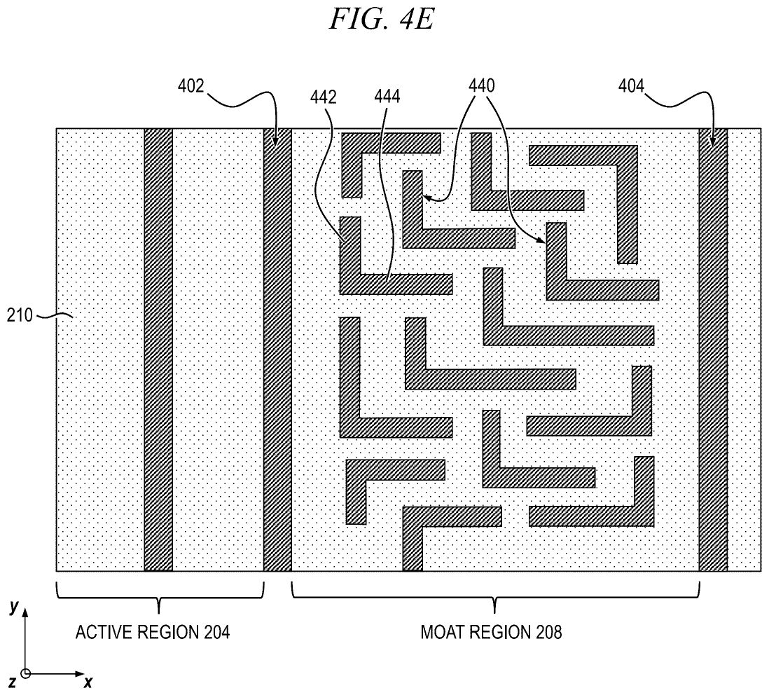

FIG. 3 is a flow diagram depicting an illustrative method 300 of fabricating a semiconductor device 200 including an enhanced moat termination structure, according to one or more embodiments of the invention. FIGS. 4A-10 are cross-sectional views depicting intermediate processes in the illustrative method 300 shown in FIG. 3, according to one or more embodiments; FIG. 4B is a top plan view depicting at least a portion of the semiconductor device 200 shown in FIG. 4A, according to one or more embodiments. Like reference numerals indicate corresponding elements throughout the several views of the drawings, and therefore detailed descriptions of elements that have been previously presented may not be repeated herein. It is to be appreciated that the dimensions shown in the figures may not necessarily be drawn to scale. Thus, for example, a cross-sectional thickness in the z direction of an element or structure in the semiconductor device 200 may be much greater than what is shown relative to a horizontal width (in the x direction and/or y direction) of the element or structure.

Referring to FIGS. 3, 4A and 4B, a substrate 202 is provided on which an epitaxial layer 210 may be formed. The substrate 202 includes an active region 204 and a moat region 208 laterally adjacent to the active region 204 (i.e., spaced apart from the active region 204 in the x direction). As previously stated, the substrate 202 may comprise an n-type substrate, although it is contemplated that a p-type substrate 202 may alternatively be employed; that is, the substrate 202 is not limited to a particular conductivity type. The epitaxial layer 210 may comprise an n-type epitaxial layer, although it is contemplated that a p-type epitaxial layer 210 may alternatively be employed; that is, the epitaxial layer 210 is not limited to a particular conductivity type. The epitaxial layer 210 may be formed having the same conductivity type as the substrate 202, although the epitaxial layer 210 may have a different doping concentration level relative to the substrate 202. For example, the epitaxial layer 210 may be more lightly doped (i.e., having a lower doping concentration level) compared to the substrate 202, although embodiments are not limited thereto.

In step 302 of the illustrative method 300, a plurality of active region trenches 402 and a plurality of moat region trenches 404 may be provided in the active region 204 and the moat region 208, respectively, of the semiconductor device 200. Optionally, one or more boundary trenches 406 may also be provided in an inactive region of the semiconductor device 200, the inactive region surrounding the active region 204 and including the moat region 208. Each of the plurality of active region trenches 402 and moat region trenches 404 may vertically extend at least partially into or through the epitaxial layer 210. In some embodiments, the trenches 402, 404 may vertically extend at least partially into the substrate 202. The trenches 402, 404 may be formed by a deep trench etch process, such as, for example, using deep reactive ion etching (DRIE), anisotropic etching, plasma etching, etc. Optionally, one or more additional trenches 410 extending from an edge of the active region 204 at least partially into the moat region 208 in the x direction and separated from one another in the y direction, may be formed. These trenches 410 may be used to form a dielectric network in the moat region 208 after step 306. This dielectric network would have more mechanical strength after step 310 (silicon etch in moat region).

It is to be appreciated that the arrangement of the trenches 404, 410 in the moat region 208 shown in FIG. 4B is merely illustrative, and that other arrangements of the trenches 404, 410 are similarly contemplated, as will be described, for example, in connection with FIGS. 4C-4E. Certain characteristics of the trenches 404, 410 in the moat region 208 may be shared across different configurations and may include, but are not limited to, (i) a width of the trenches 404, 410 in moat region 208 (e.g., in the x direction for trenches 404, or in the y direction for trenches 410) is about the same as the width in the x direction of the active trenches 402 in the active region 204 (e.g., ±about 30 percent), and (ii) a shortest distance between adjacent trenches 404, 410 in the moat region 208 should not exceed about twice the width of trenches 404, 410.

The active region trenches 402 and moat region trenches 404 may be formed having a high aspect ratio. For example, in one or more embodiments, a ratio of trench depth in the z direction to trench width in the x direction may be equal to or greater than about 40:1. Thus, assuming a trench width of about 1 μm, a depth of the trenches 402, 404 may be about 40 μm or more. The width in the x direction of each of the moat region trenches 404 may be the same as the width in the x direction of each of the active region trenches 402, although embodiments are not limited thereto. In one or more embodiments the moat region trenches 404 may be formed during the same deep trench etching step as is used to form the active region trenches 402. Furthermore, a lateral spacing in the x direction between adjacent moat region trenches 404 may be different than a lateral spacing in the x direction between adjacent active region trenches 402. For example, in one or more embodiments a mesa width, w1, in the active region 204 may be greater than a mesa width, w2, in the moat region 208. The term “mesa” as used herein is intended to broadly refer to the semiconductor material (e.g., epitaxial layer 210) between adjacent trenches.

As previously stated, the arrangement of trenches 404 and 410 in the moat region 208 shown in FIG. 4B is merely illustrative, and various other configurations of the trenches 404, 410 are similarly contemplated. By way of example only and without limitation, FIGS. 4C-4E are top plan views depicting at least a portion of example alternative configurations of an enhanced moat termination structure in a semiconductor device, according to embodiments of the inventive concept. Referring to FIG. 4C, the moat region 208 includes a plurality of moat region trench structures 420 distributed throughout the moat region 208. Each of the moat trench structures 420 may be shaped as a cross, including a first trench portion 422 extending in the y direction and a second trench portion 424 extending in the x direction. In this exemplary embodiment, a length (in the y direction) of the first trench portion 422 and a length (in the x direction) of the second trench portion 424 of each moat trench structure 420 may be about equal, although embodiments are not limited thereto.

The plurality of moat trench structures 420 are spaced apart from one another in the x direction by a width w3 and in the y direction by a width w4. In some embodiments, the widths w3 and w4 are about equal to a lateral width of the first trench portion 422 or second trench portion 424, although embodiments are not limited thereto. For example, in one or more embodiments, the spacing (w3, w4) between adjacent moat trench structures 420 may be less than or equal to about three times (3×) the lateral width of the first trench portion 422 (in the x direction) or the second trench portion 424 (in the y direction), or the spacing between adjacent moat trench structures 420 may be less than or equal to about two times (2×) the lateral width of the first trench portion 422 or the second trench portion 424, or the spacing between adjacent moat trench structures 420 may be less than or equal to about one and a half times (1.5×) the lateral width of the first trench portion 422 or the second trench portion 424. The spacing between adjacent moat trench structures 420 may be varied or otherwise controlled so as to achieve a prescribed mechanical stability of the semiconductor device for a given trench depth.

Referring to FIG. 4D, the moat region 208 includes a plurality of moat region trench structures 430 distributed throughout the moat region 208. Each of the moat trench structures 430 may be hexagonally shaped, with the epitaxial layer 210 between adjacent moat region trench structures 430 forming a honeycomb pattern. Likewise, in FIG. 4E, the moat region 208 includes a plurality of moat trench structures 440 distributed throughout the moat region 208. In this illustrative embodiment, each of the moat trench structures 440 may have an L-shaped configuration when viewed in plan view, including a first portion 442 extending in the y-direction and a second portion 444 extending from the first portion 442 in the x-direction. The alternative moat structure embodiments shown in FIGS. 4D and 4E may provide more uniform filling with TEOS material (e.g., TEOS film) after a moat etch step especially at the active region trenches 402, which is an interface to the active region 204. This configuration may provide a more uniform potential distribution in the active region 204.

With continued reference to FIGS. 3 and 4A, in step 304, a first high-quality dielectric deposition may be performed whereby a first high-quality dielectric layer (e.g., film) 220 may be provided on sidewall and bottom surfaces of each of the active region trenches 402, moat region trenches 404, and boundary trench 406 (if present). The first high-quality dielectric layer 220 is also provided on an upper surface of the mesas between adjacent trenches 402, 404. The first high-quality dielectric layer 220 may be formed by blanket deposition, for example using tetraethoxysilane (TEOS) as a silicon dioxide (SiO2) source, whereby TEOS material is conformally deposited (e.g., using plasma-enhanced chemical vapor deposition (PECVD), sub-atmospheric pressure chemical vapor deposition (SACVD), or atomic layer deposition (ALD)) on exposed silicon material (including the epitaxial layer 210 and the substrate 202) defining the sidewalls and bottom of each of the active region trenches 402 and moat region trenches 404 and on the mesas between the trenches 402, 404. In a TEOS deposition process, TEOS is transported via a carrier gas to the hot surface of the wafer, where TEOS is dissociated. A certain amount of the decomposition products will adhere on the surface and build a silicon dioxide layer while the remaining particles are reflected from the surface.

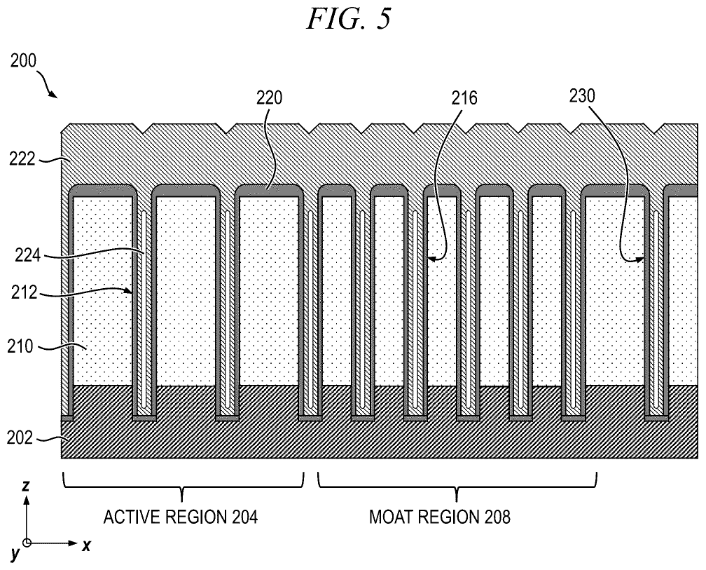

With reference to FIGS. 3 and 5, a second high-quality dielectric deposition process may be performed in step 306. During the second high-quality dielectric deposition process, a second high-quality dielectric layer (e.g., film) 222 is formed on the first high-quality dielectric layer 220. The second high-quality dielectric layer 222 may comprise, for example, borophosphosilicate glass (BPSG), although embodiments are not limited thereto. The second high-quality dielectric layer 222 may conformally cover sidewalls and a bottom of each of the active region trenches 402 and moat region trenches 404. In one or more embodiments, the second high-quality dielectric deposition is configured such that a first air gap 224 is present in each of at least a subset of the trenches 402, 404; that is, the second high-quality dielectric deposition is configured such that facing surfaces of the second high-quality dielectric layer 222 on opposing sidewalls of each of the trenches 402, 404 do not contact one another, thereby leaving a first air gap 224 therebetween (i.e., in a center of each of the trenches 402, 404). The term “contact” (or “contacting,” or like terms such as, for example, “connect” or “connecting”), as may be used herein, is intended to refer to a physical and/or electrical connection between two or more elements, and may include other intervening elements. As used herein, the term “and/or” includes any and all combinations of one or more of the associated listed items.

A width of the first air gap 224 in the x direction in each of the active region trenches 402 and moat region trenches 404 may be controlled as a function of one or more parameters of the second high-quality dielectric deposition process (e.g., deposition rate, temperature, concentration of impurities, such as boron and phosphorus, in the BPSG layer (which may facilitate a reflow process), etc.). A reflow process may then be performed in step 306 to cover (e.g., pinch off) an upper portion (i.e., opening) of each of the trenches 402, 404 with the second high-quality dielectric layer 222. In step 306, the second high-quality dielectric deposition may be performed at a first temperature that is below a reflow temperature of the material used to form the second high-quality dielectric layer 222 (e.g., BPSG) and a second temperature, greater than the first temperature, is used during the reflow process that is sufficient to reflow the second high-quality dielectric layer 222. By way of example only and without limitation, a TEOS deposition may occur at about 550 degrees Celsius, and a BPSG deposition may occur at about the same temperature. However, a following reflow process may occur at temperatures greater than about 900 degrees Celsius for about 30 minutes. As a result, a plurality of active trench structures 212 may be provided in the active region 204 and a plurality of dielectric pillars 216 may be provided in the moat region 208. In some embodiments, one or more boundary trench structures 230 may also be provided proximate an edge of the IC die 200, outside of the moat region 208.

As previously stated, the trenches 402, 404 may be configured having a high aspect ratio (e.g., about 30:1 or greater), which may be defined as a ratio of the trench height in the z direction to the trench width in the x direction. In general, as a trench gets narrower and the aspect ratio increases, it becomes more likely that the opening at the upper portion of the trench will “pinch off” during the reflow process. Pinching off a trench traps a void (i.e., air gap) within the trench. Under certain conditions (e.g., when the trench is wide and has a relatively low aspect ratio), the void will be filled during the reflow process; however, as the trench becomes narrower in width, it becomes more likely that the void will not be filled during the reflow process, thus forming the first air gap 224.

Optionally, a dielectric (oxide) thinning process may be performed in step 307 to reduce a cross-sectional thickness of the second high-quality dielectric layer (film) 222 on the upper surface of the IC die 200. A blanket etch process may be used for the dielectric thinning process, although embodiments are not limited thereto. A determination as to whether or not the dielectric thinning process is performed may depend on a cross-sectional thickness of the second high-quality dielectric layer 222 on the upper surface of the IC die 200 prior to formation of an opening for the moat region in step 308. For example, if the thickness of the second high-quality dielectric layer 222 is about 0.5 um or less, the dielectric thinning process (step 307) may be eliminated.

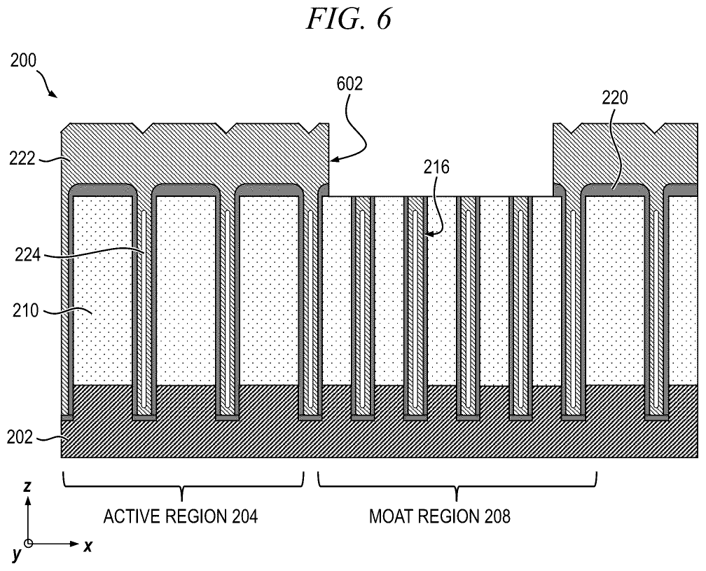

Referring now to FIGS. 3 and 6, an oxide etch process is performed in step 308 to provide an opening 602 in the moat region 208. The opening 602 may be formed by etching through the second high-quality dielectric layer 222 and first high-quality dielectric layer 220 vertically overlapping a portion of the moat region 208. The term “overlapping” (or “overlaps,” or like terms), as may be used herein, is intended to broadly refer to a first element that intersects with at least a portion of a second element in the vertical direction (i.e., the z direction), but does not require that the first and second elements be completely aligned with one another in a horizontal plane (i.e., in the x direction and/or the y direction). The opening 602 may be defined using a photolithographic patterning process, whereby portions of the IC die that are not intended to be etched are protected using a hard mask and portions of the IC die to be etched are left exposed.

During the oxide etch process in step 308, which may be an anisotropic etch selective to oxide, the upper surface of the epitaxial layer 210 may be used as an etch stop layer. An upper portion of each of at least a subset of the dielectric pillars 216 in the moat region 208, as well as the upper surface of the epitaxial layer 210 forming mesas between adjacent dielectric pillars 216, may be exposed through a bottom of the opening 602.

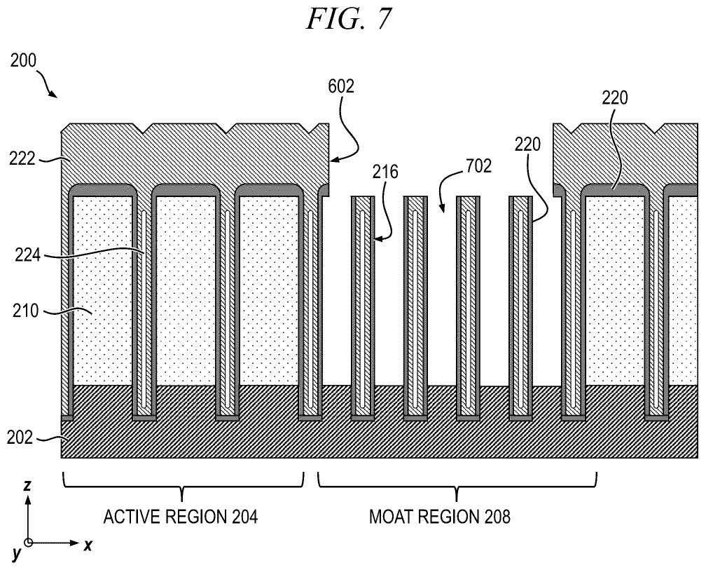

With reference to FIGS. 3 and 7, in step 310 a deep etch may be performed in the moat region 208. In one or more embodiments, the deep etch may be an isotropic etch, a process that selectively etches both laterally (i.e., x and/or y direction) and vertically (i.e., z direction). The deep etch may be selective to silicon to remove portions of the epitaxial layer 210 forming the mesas between adjacent dielectric pillars 216 that are exposed through the bottom of the opening 602 in the moat region 208. In performing the deep etch, the upper surface of the substrate 202 may be used as an etch stop layer. As a result of the deep etch, a plurality of trenches 702 are formed, with each of the trenches 702 having sidewalls defined by the first high-quality dielectric layer 220 on the sidewalls of the dielectric pillars 216 and having a bottom defined by the upper surface of the substrate 202 exposed through the trenches 702.

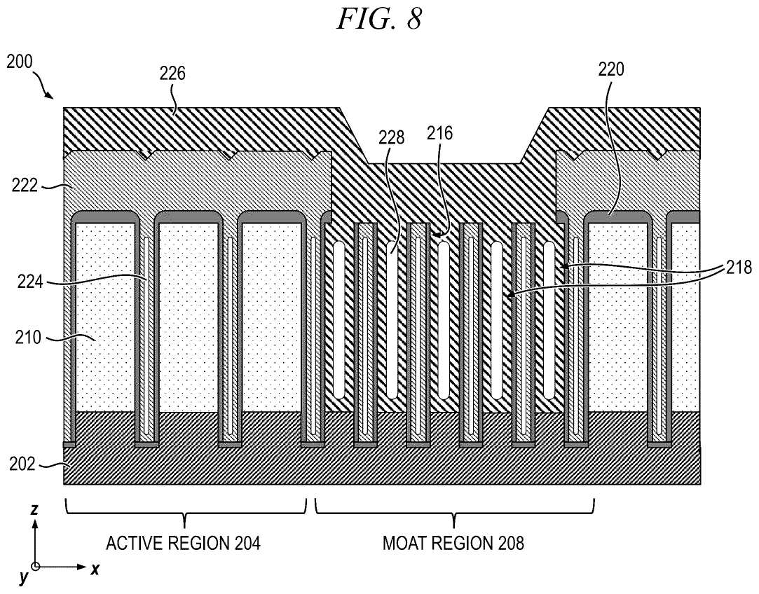

In step 312, a third high-quality dielectric deposition process may be performed. During the third high-quality dielectric deposition process, a third high-quality dielectric layer (e.g., film) 226 is formed on the sidewalls and bottom surfaces of each of the trenches 702 exposed through the opening 602 (FIG. 7) in the moat region 208, as shown in FIG. 8. The third high-quality dielectric layer 226 may comprise, for example, BPSG, although embodiments are not limited thereto. The third high-quality dielectric layer 226 may conformally cover sidewalls and a bottom of each of the trenches 702 between adjacent dielectric pillars 216. In one or more embodiments, the third high-quality dielectric deposition is configured such that a second air gap 228 is present in each of at least a subset of the trenches 702; that is, the third high-quality dielectric deposition is configured such that facing surfaces of the third high-quality dielectric layer 226 on opposing sidewalls of each of the trenches 702 do not contact one another, thereby leaving an interior space forming the second air gap 228 therebetween (i.e., in a center of each of the trenches 702).

A width of the second air gap 228 in the x direction in each of the trenches 702 (FIG. 7) may be controlled as a function of one or more parameters of the third high-quality dielectric deposition process (e.g., deposition rate, temperature, etc.). Primarily, a width of the second air gap 228 may be controlled as a function of a thickness of the first deposited high-quality dielectric material (e.g., TEOS). A reflow process may then be performed in step 312 to cover (e.g., pinch off) an upper portion (i.e., opening) of each of the trenches 702 with the third high-quality dielectric layer 226 to enclose an interior space within each of the trenches 702 forming the second air gap. In some embodiments, the interior space of each of the trenches 702 may be at least partially filled with a gas (other than or in addition to air) to form the second air gap 228. The third high-quality dielectric layer 226 may at least partially fill the opening 602 (FIG. 6) in the moat region 208 and may extend laterally (i.e., in the x direction) onto at least a portion of an upper surface of the second high-quality dielectric layer 222 outside of the moat region 208, such as in the active region 204 and a portion of the inactive region at an edge of the IC die 200. As a result, a plurality of high-quality dielectric structures 218 may be provided between adjacent dielectric pillars 216 in the moat region 208.

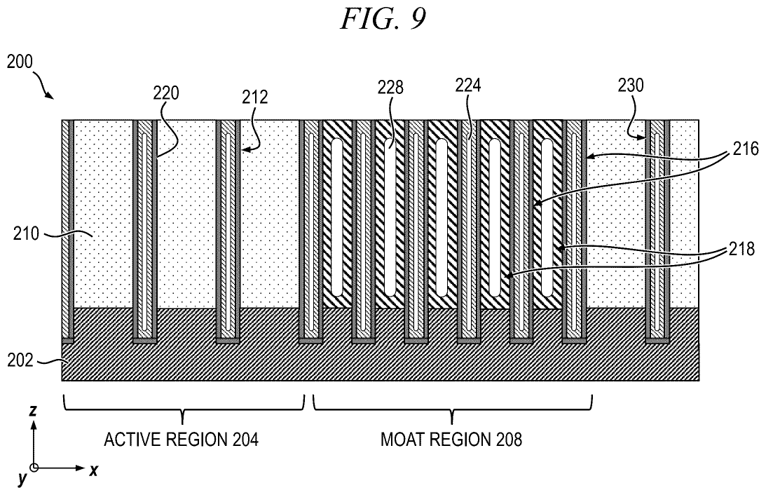

Referring to FIGS. 3 and 9, a planarization process may be performed in step 314 to substantially planarize the upper surface of the IC die 200. Surface planarization may be performed using, for example, chemical mechanical polishing or planarization (CMP) and/or etching (wet and/or dry etching), although embodiments are not limited thereto. During surface planarization in step 314, portions of the third high-quality dielectric layer 226, the second high-quality dielectric layer 222 and the first high-quality dielectric layer 220 may be removed such that an upper surface of the epitaxial layer 210 forming mesas between active region trench structures 212 is exposed.

The resulting structure shown in FIG. 9 provides a moat termination structure in the moat region 208 comprising a plurality of dielectric pillars 216 alternating with high-quality dielectric structures 218 arranged in the x direction; that is, the high-quality dielectric structures 218 may be provided between adjacent dielectric pillars 216 in the moat region 208. Each of at least a subset of the high-quality dielectric structures 218 includes a second air gap 228. In one or more embodiments, each of at least a subset of the dielectric pillars 216 includes a first air gap 224. The first and second air gaps 224 and 228 formed in the dielectric pillars 216 and the high-quality dielectric structures 218, respectively, may beneficially reduce mechanical stresses in the IC die 200

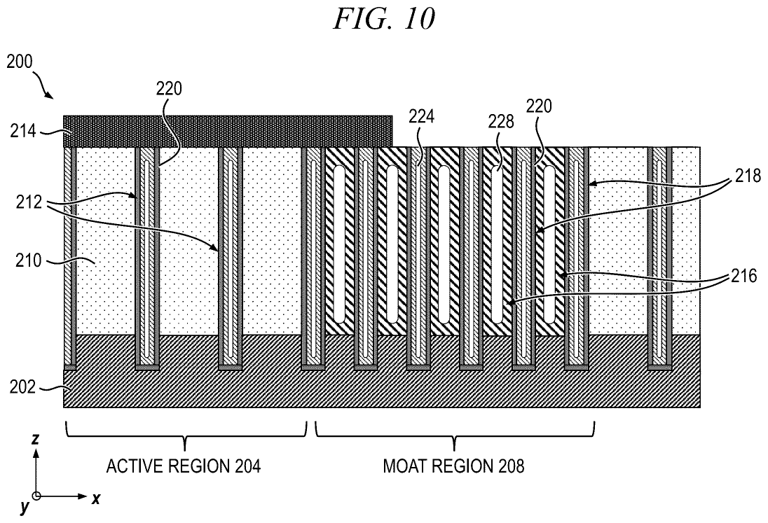

With reference to FIGS. 3 and 10, a metallization process may be performed in step 316. As part of the metallization process, a metal layer (or other conductive material) may be formed on the upper surface of the IC die 200. The metallization process may involve, for example, a vacuum deposition technique, although embodiments are not limited thereto. The metal layer may be patterned (e.g., using standard photolithography) to form a metal electrode 214 on a portion of the upper surface of the IC die 200. In this illustrative embodiment, the metal electrode 214 is arranged to extend laterally (i.e., in the x direction and/or y direction) on at least a portion of the exposed upper surfaces of the epitaxial layer 210 and active region trench structures 212 in the active region 204. The metal electrode 214 may electrically connect the active region trench structures 212 to a prescribed potential. In one or more embodiments, the metal electrode 214 may extend laterally over a portion of the moat region 208 and serve as a field plate for controlling a distribution of electric fields in the IC die 200. The metallization process may also be used to provide electrical connection (e.g., electrodes, wiring traces, etc.) to one or more devices formed in the active region 204 of the IC die 200.

In step 318, a passivation layer 232 (see FIG. 2A) may be optionally formed on at least a portion of the upper surface of the IC die 200. For example, in one or more embodiments, the passivation layer 232 may cover (i.e., be on or over) the upper surface of the moat region 208 and may extend laterally onto a portion of the metal electrode 214 in the active region 204, as shown in FIG. 2A. The passivation layer 232, which may comprise an organic insulating material (e.g., polyimide), can provide environmental protection and electrical isolation for the IC die 200.

Although the present disclosure provides a specific non-limiting example of an illustrative enhanced moat termination structure for use in a charge balanced semiconductor device, various modifications and changes can be made thereto without departing from the scope of the disclosure as set forth in the claims below, as will become apparent to those skilled in the art given the teachings herein. Accordingly, the specification and figures are to be regarded in an illustrative rather than a restrictive sense, and all such modifications are intended to be included within the scope of the present disclosure. Any benefits, advantages, or solutions to problems that are described herein with regard to a specific example are not intended to be construed as a critical, required, or essential feature or element of any or all of the claims.

Although the overall fabrication methods and the structures formed thereby may be entirely novel, certain individual processing steps required to implement the method according to one or more embodiments of the present inventive concept may utilize conventional semiconductor fabrication techniques and conventional semiconductor fabrication tooling. These techniques and tooling will already be familiar to those having ordinary skill in the relevant arts given the teachings herein. Moreover, many of the processing steps and tooling used to fabricate semiconductor devices are also described in a number of readily available publications, including, for example: P. H. Holloway et al., Handbook of Compound Semiconductors: Growth, Processing, Characterization, and Devices, Cambridge University Press, 2008; and R. K. Willardson et al., Processing and Properties of Compound Semiconductors, Academic Press, 2001, which are both hereby incorporated herein by reference in their entireties for all purposes. It is emphasized that while some individual processing steps are set forth herein, those steps are merely illustrative, and one skilled in the art may be familiar with several equally suitable alternatives that would also fall within the scope of the invention.

It is to be appreciated that the various layers and/or regions shown in the accompanying figures may not be drawn to scale. Furthermore, one or more semiconductor layers of a type commonly used in such semiconductor devices may not be explicitly shown in a given figure to facilitate a clearer description. This does not imply that the semiconductor layer(s) not explicitly shown are omitted in the actual device.

In one or more embodiments, formation of the exemplary device structures described herein may involve deposition of certain materials and layers by physical vapor deposition (PVD), chemical vapor deposition (CVD), atomic layer deposition (ALD), molecular beam epitaxy (MBE), or any of the various modifications thereof, including, for example, plasma-enhanced chemical vapor deposition (PECVD), metal-organic chemical vapor deposition (MOCVD), low pressure chemical vapor deposition (LPCVD), electron-beam physical vapor deposition (EB-PVD), and plasma-enhanced atomic layer deposition (PE-ALD). The depositions can be epitaxial processes, and the deposited material can be crystalline. In one or more embodiments, formation of a layer can be achieved using a single deposition process or multiple deposition processes, where, for example, a conformal layer is formed by a first process (e.g., ALD, PE-ALD, etc.) and a fill is formed by a second process (e.g., CVD, electrodeposition, PVD, etc.); the multiple deposition processes can be the same or different.

As used herein, the term “semiconductor” may refer broadly to an intrinsic semiconductor material that has been doped, that is, into which a doping agent (i.e., dopant) has been introduced, giving it different electrical properties than the intrinsic semiconductor material, or it may refer to intrinsic semiconductor material that has not been doped. Doping may involve adding dopant atoms to an intrinsic semiconductor material, which thereby changes electron and hole carrier concentrations and/or other properties of the intrinsic semiconductor material at thermal equilibrium. Dominant carrier concentration in an extrinsic semiconductor material determines the conductivity type of the semiconductor material.

The term “metal,” as used herein, is intended to refer to any electrically conductive material, regardless of whether the material is technically defined as a metal from a chemistry perspective or not. Thus “metals” as used herein will include such materials as, for example, aluminum, copper, silver, gold, etc., and may also include such materials as, for example, graphene, germanium, gallium arsenide, highly-doped polysilicon (commonly used in most MOSFET devices), etc. This is to be distinguished from the definition of a “metal” from a physics perspective, which usually refers to those elements having a partially filled conduction band and having lower resistance toward lower temperature.

As used herein, the term “insulating” may generally denote a material having a room temperature conductivity of less than about 10⁻¹⁰ (Ω−m)⁻¹. Suitable insulating materials may include, but are not limited to, silicon oxide, silicon nitride, silicon oxynitride, boron nitride, high-dielectric constant (high-k) materials, or any combination of these materials. Non-limiting examples of high-k materials may include, for example, metal oxides, such as hafnium oxide, hafnium silicon oxide, hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate, ceramics, etc. High-k materials may further include dopants such as lanthanum, aluminum, etc.

As used herein, “p-type” may refer broadly to the addition of impurities to an intrinsic semiconductor material that creates deficiencies of valence electrons. In a silicon-containing material, non-limiting examples of p-type dopants (i.e., impurities) include boron, aluminum, gallium and indium.

As used herein, “n-type” may refer broadly to the addition of impurities that contribute free electrons to an intrinsic semiconductor material. In a silicon-containing material, non-limiting examples of n-type dopants include antimony, arsenic and phosphorous.

It will also be understood that when an element such as a layer, region or substrate is referred to as being “atop,” “above,” “on” or “over” another element, it is broadly intended that the element be in direct contact with the other element or intervening elements can also be present. In contrast, when an element is referred to as being “directly on” or “directly over” another element, it is intended that there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present. Furthermore, positional (i.e., directional) terms such as “above,” “below,” “upper,” “lower,” “under,” and “over” as may be used herein, are intended to indicate relative positioning of elements or structures to each other as opposed to absolute position.

At least a portion of the techniques of the present inventive concept may be implemented in an integrated circuit. In forming integrated circuits, identical die are typically fabricated in a repeated pattern on a surface of a semiconductor wafer. Each die includes a device or structure described herein, and may include other structures, elements and/or circuits. The individual die are cut or diced from the wafer, then packaged as an integrated circuit. One skilled in the art would know how to dice wafers and package die to produce integrated circuits. Any of the exemplary structures illustrated in the accompanying figures, or portions thereof, may form part of an integrated circuit. Integrated circuits so manufactured are considered part of this invention.

Those skilled in the art will appreciate that the exemplary structures discussed above can be distributed in raw form (i.e., a single wafer having multiple unpackaged chips), as bare dies, in packaged form, or incorporated as parts of intermediate products or end products that benefit from having enhanced moat termination structures therein (e.g., power IC devices) formed in accordance with one or more embodiments of the present disclosure.

An integrated circuit in accordance with aspects of the present disclosure can be employed in essentially any application and/or electronic system involving enhanced breakdown voltage structures, such as, but not limited to, power metal-oxide semiconductor field-effect transistors (MOSFETs), Schottky diodes, etc. Suitable systems and applications for implementing embodiments of the invention may include, but are not limited to, AC-DC and DC-DC conversion, motor control, and power supply OR-ing (“OR-ing” is a particular type of application that parallels multiple power supplies to one common power bus in a redundant power system architecture). Systems incorporating such integrated circuits are considered part of this invention. Given the teachings of the present disclosure provided herein, one of ordinary skill in the art will be able to contemplate other implementations and applications of embodiments of the invention.

The illustrations of embodiments of the invention described herein are intended to provide a general understanding of the various embodiments, and they are not intended to serve as a complete description of all the elements and features of apparatus and systems that might make use of the structures and semiconductor fabrication methodologies described herein. Many other embodiments will become apparent to those skilled in the art given the teachings herein; other embodiments are utilized and derived therefrom, such that structural and logical substitutions and changes can be made without departing from the scope of this disclosure. The drawings are also merely representational and are not necessarily drawn to scale. Accordingly, the specification and drawings are to be regarded in an illustrative rather than a restrictive sense.

Embodiments of the invention are referred to herein, individually and/or collectively, by the term “embodiment” merely for convenience and without intending to limit the scope of this application to any single embodiment or inventive concept if more than one is, in fact, shown. Thus, although specific embodiments have been illustrated and described herein, it should be understood that an arrangement achieving the same purpose can be substituted for the specific embodiment(s) shown; that is, this disclosure is intended to cover any and all adaptations or variations of various embodiments. Combinations of the above embodiments, and other embodiments not specifically described herein, will become apparent to those of skill in the art given the teachings herein.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof.

The corresponding structures, materials, acts, and equivalents of all means or step-plus-function elements in the claims below are intended to include any structure, material, or act for performing the function in combination with other claimed elements as specifically claimed. The description of the various embodiments has been presented for purposes of illustration and description, but is not intended to be exhaustive or limited to the forms disclosed. Many modifications and variations will be apparent to those of ordinary skill in the art without departing from the scope and spirit of the invention. The embodiments were chosen and described in order to best explain the principles of the invention and the practical application, and to enable others of ordinary skill in the art to understand the various embodiments with various modifications as are suited to the particular use contemplated.

The abstract is provided to comply with 37 C.F.R. § 1.72(b), which requires an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the appended claims reflect, inventive subject matter lies in less than all features of a single embodiment. Thus, the following claims are hereby incorporated into the Detailed Description, with each claim standing on its own as separately claimed subject matter.

Given the teachings of embodiments of the invention provided herein, one of ordinary skill in the art will be able to contemplate other implementations and applications of the techniques of embodiments of the invention. Although illustrative embodiments of the invention have been described herein with reference to the accompanying drawings, it is to be understood that embodiments of the invention are not limited to those precise embodiments, and that various other changes and modifications are made therein by one skilled in the art without departing from the scope of the appended claims.

1. A moat termination structure for use in a semiconductor device including an active region, in which one or more active devices are formed, and an edge termination region adjacent to the active region, in which the moat termination structure is formed, the moat termination structure comprising:
a plurality of dielectric pillars in the edge termination region, each of the plurality of dielectric pillars extending in a first direction perpendicular to an upper surface of the semiconductor device; and
one or more dielectric structures in the edge termination region, each of the dielectric structures extending in the first direction and disposed between two of the plurality of dielectric pillars adjacent to one another in a second direction parallel to the upper surface of the semiconductor device.

2. The moat termination structure according to claim 1, wherein each dielectric pillar in at least a subset of the plurality of dielectric pillars comprises:
a first dielectric material layer defining sidewalls and a bottom of the dielectric pillar; and
a second dielectric material layer on the sidewalls and the bottom of the first dielectric material layer, sidewalls and top and bottom surfaces of the second dielectric material layer defining a first interior space of the dielectric pillar.

3. The moat termination structure according to claim 2, wherein the first interior space of each dielectric pillar in at least the subset of the plurality of dielectric pillars is enclosed on all sides.

4. The moat termination structure according to claim 2, wherein the first interior space of each dielectric pillar in at least the subset of the plurality of dielectric pillars comprises a first air gap.

5. The moat termination structure according to claim 2, wherein the first interior space of each dielectric pillar in at least the subset of the plurality of dielectric pillars is at least partially filled with a gas.

6. The moat termination structure according to claim 2, wherein the first dielectric material layer comprises tetraethyl orthosilicate film, and wherein the second dielectric material layer comprises borophosphosilicate glass.

7. The moat termination structure according to claim 2, wherein each dielectric structure of the one or more dielectric structures comprises:
a third dielectric material layer defining sidewalls and top and bottom surfaces of the dielectric structure; and
a second interior space defined by the third dielectric material layer.

8. The moat termination structure according to claim 7, wherein the second interior space of each of the one or more dielectric structures comprises a second air gap.

9. The moat termination structure according to claim 7, wherein the second interior space of each dielectric structure of the one or more dielectric structures is at least partially filled with a gas.

10. The moat termination structure according to claim 7, wherein each dielectric pillar in at least a subset of the plurality of dielectric pillars extends in the first direction at least partially into a substrate of the semiconductor device, and wherein each of the one or more dielectric structures is disposed on an upper surface of the substrate.

11. The moat termination structure according to claim 7, wherein a first width in the second direction of each of the one or more dielectric structures is greater than a second width in the second direction of each of the plurality of dielectric pillars.

12. The moat termination structure according to claim 7, wherein the third dielectric material layer comprises borophosphosilicate glass.

13. The moat termination structure according to claim 1, further comprising a metal layer, the metal layer extending in the second direction on a portion of an upper surface of the moat termination structure.

14. The moat termination structure according to claim 1, further comprising one or more trench structures in the edge termination region, each of the one or more trench structures extending in a third direction parallel to the upper surface of the semiconductor device and intersecting the second direction, the one or more trench structures being configured to provide mechanical stability to the semiconductor device.

15. The moat termination structure according to claim 1, wherein each of at least a subset of the plurality of dielectric pillars in the edge termination region comprises:
a first trench portion extending in the second direction; and
a second trench portion extending in a third direction parallel to the upper surface of the semiconductor device and intersecting the second direction,
wherein the first and second trench portions are cross-shaped when viewed in plan view.

16. The moat termination structure according to claim 1, wherein each of at least a subset of the plurality of dielectric pillars is hexagonally-shaped when viewed in plan view.

17. The moat termination structure according to claim 1, wherein each of at least a subset of the plurality of dielectric pillars in the edge termination region comprises:
a first trench portion extending in the second direction; and
a second trench portion extending in a third direction parallel to the upper surface of the semiconductor device and intersecting the second direction,
wherein the first and second trench portions are L-shaped when viewed in plan view.

18. A semiconductor device, comprising:
a semiconductor layer structure comprising a drift region, the drift region including an active region, comprising at least one active element therein, and an edge termination region extending around at least a portion of a perimeter of the active region when viewed in plan view; and
a moat termination structure in the edge termination region, the moat termination structure comprising:
a plurality of dielectric pillars, each of the plurality of dielectric pillars extending at least partially through the drift region in a first direction perpendicular to an upper surface of the semiconductor layer structure; and
one or more dielectric structures, each of the one or more dielectric structures extending at least partially through the drift region in the first direction and disposed between two of the plurality of dielectric pillars adjacent to one another in a second direction parallel to the upper surface of the semiconductor layer structure.

19. The semiconductor device according to claim 18, further comprising a plurality of active trench structures in the active region, each of the plurality of active trench structures extending at least partially through the drift region in the first direction and being spaced apart from one another in the second direction.

20. The semiconductor device according to claim 19, wherein a first spacing between adjacent active trench structures of the plurality of active trench structures in the second direction is greater than a second spacing between adjacent dielectric pillars of the plurality of dielectric pillars in the second direction.

21. The semiconductor device according to claim 19, wherein a first depth in the first direction of each of the plurality of active trench structures is about the same as a second depth in the first direction of each of the plurality of dielectric pillars, relative to the upper surface of the semiconductor layer structure as a reference layer.

22. The semiconductor device according to claim 19, wherein a first width in the second direction of each of the plurality of active trench structures is about the same as a second width in the second direction of each of the plurality of dielectric pillars.

23. The semiconductor device according to claim 18, wherein each dielectric pillar in at least a subset of the plurality of dielectric pillars comprises:
a first dielectric material layer defining sidewalls and a bottom of the dielectric pillar; and
a second dielectric material layer on the sidewalls and the bottom of the first dielectric material layer, sidewalls and top and bottom surfaces of the second dielectric material layer defining a first interior space of the dielectric pillar.

24.-27. (canceled)

28. The semiconductor device according to claim 23, wherein each of the one or more dielectric structures comprises:
a third dielectric material layer defining sidewalls and top and bottom surfaces of the dielectric structure; and
a second interior space defined by the third dielectric material layer.

29. (canceled)

30. (canceled)

31. The semiconductor device according to claim 18, further comprising a metal layer on at least a portion of the upper surface of the semiconductor layer structure in the active region, the metal layer extending in the second direction from the active region into a portion of the edge termination region of the semiconductor device.

32.-39. (canceled)
